(19) United States
(12) Patent Application Publication
(10) Pub. No.: US 2026/0271435 A1
(43) Pub. Date: Sep. 10, 2026

(54) LIGHT EMITTING DEVICE

(71) Applicant: AUO Corporation, Hsinchu City (TW)

(72) Inventor: I-Hsun Hsieh, Hsinchu City (TW)

(73) Assignee: AUO Corporation, Hsinchu City (TW)

(21) Appl. No.: 19/221,473

(22) Filed: May 28, 2025

(30) Foreign Application Priority Data
Mar. 10, 2025 (TW) 114108771

(51) Int. Cl. H10H 20/813; H10H 20/85; H10H 20/854; H10H 20/857

(52) U.S. Cl. CPC H10H 20/8131; H10H 20/8508; H10H 20/854; H10H 20/857

(57) ABSTRACT

Provided is a light emitting device, including a substrate; a first light emitting chip for emitting first color light, the first light emitting chip being disposed on the substrate, the first light emitting chip including a first substrate and a first light emitting layer, the first substrate including first surface and second surface opposite to the first surface, the first light emitting layer being positioned on the first surface; a second light emitting chip for emitting second color light different from the first color light, the second light emitting chip being disposed on the first light emitting chip, the second light emitting chip including a second substrate and a second light emitting layer, the second substrate including third surface and fourth surface opposite to the third surface, the second light emitting layer being positioned on the third surface; the second surface being opposite to the fourth surface.

### CROSS-REFERENCE TO RELATED APPLICATION

This application claims the priority benefit of Taiwan application serial no. 114108771, filed on March 10, 2025. The entirety of the above-mentioned patent application is hereby incorporated by reference herein and made a part of this specification.

### BACKGROUND

### Technical Field

The disclosure relates to a light emitting device.

### Description of Related Art

Currently, in various application scenarios, there is a considerable demand for high color rendering light emitting devices. Therefore, the method of using blue light emitting elements matched with red phosphor and green phosphor to generate blue light, red light, and green light is no longer sufficient, and it is necessary to use blue light emitting elements and green light emitting elements matched with red phosphor to generate blue light, red light, and green light. One important problem to be solved is how to improve the color mura problem between different color lights in the light emitting element, such as between blue light and green light.

### SUMMARY

The disclosure provides a light emitting device to improve a color mura problem between different color light in light emitting elements.

A light emitting device of the disclosure includes a substrate; a first light emitting chip to emit first color light, the first light emitting chip being disposed on the substrate, the first light emitting chip including a first substrate and a first light emitting layer, the first substrate including a first surface and a second surface opposite to the first surface, the first light emitting layer being positioned on the first surface; a second light emitting chip to emit second color light different from the first color light, the second light emitting chip being disposed on the first light emitting chip, the second light emitting chip including a second substrate and a second light emitting layer, the second substrate including a third surface and a fourth surface opposite to the third surface, the second light emitting layer being positioned on the third surface; wherein the second surface and the fourth surface are opposite to each other.

Based on the above, by means of connecting the first light emitting chip to the substrate by a flip chip method, and connecting the second light emitting chip positioned on the first light emitting chip to the substrate by a mount method, the color mura phenomenon between different color light may be effectively improved.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic diagram of a light emitting device according to an embodiment of the disclosure.

FIG. 2 is a circuit schematic diagram of a first light emitting chip and a second light emitting chip according to an embodiment of the disclosure.

FIG. 3 is a schematic diagram of a light emitting device according to an embodiment of the disclosure.

FIG. 4 to FIG. 9 are process flow diagrams for manufacturing a light emitting device according to an embodiment of the disclosure.

### DESCRIPTION OF THE EMBODIMENTS

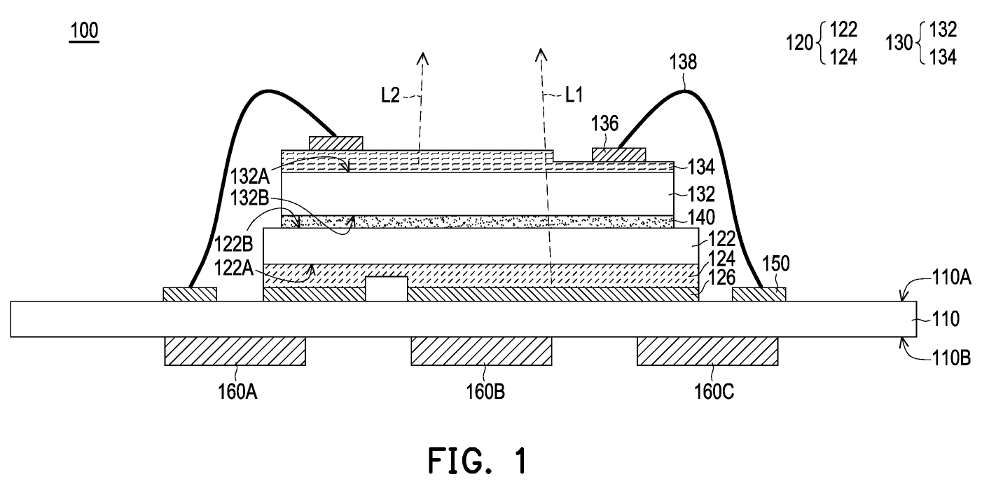

FIG. 1 is a schematic diagram of a light emitting device according to an embodiment of the disclosure. Referring to FIG. 1, a light emitting device 100 includes a substrate 110, a common metal layer 126, a first light emitting chip 120, a second light emitting chip 130, a die attach layer 140, a bonding pad 150, and an electrode 160.

The substrate 110 is used to provide support for the light emitting device 100. The substrate 110 has a surface 110A and a surface 110B opposite to each other. Multiple bonding pads 150 are positioned on the surface 110A of the substrate 110. Multiple electrodes are disposed on the surface 110B, for example, a first anode 160A, a cathode 160B, and a second anode 160C. Some of the multiple bonding pads 150 are electrically connected through the substrate 110 with some of the multiple electrodes. In some embodiments, the substrate 110 may be a printed circuit board (PCB), or other elements with similar function, and the disclosure is not limited thereto.

As shown in FIG. 1, the first light emitting chip 120 is electrically connected to the substrate 110 by means of a flip chip method. The second light emitting chip 130 is electrically connected to the substrate 110 by means of a mount method.

Specifically, the first light emitting chip 120 is disposed on the substrate 110, used to emit first color light L1. The first light emitting chip 120 includes a first substrate 122 and a first light emitting layer 124.

The first substrate 122 includes a first surface 122A, and a second surface 122B opposite to the first surface 122A. In some embodiments, the material of the first substrate 122 may be aluminum oxide, namely sapphire, or materials with similar property, and the disclosure is not limited thereto. In some embodiments, the first substrate 122 is transparent to the first color light L1, to prevent absorption of the first color light L1.

The first light emitting layer 124 is positioned on the first surface 122A, used to emit the first color light L1. Specifically, the first light emitting layer 124 of the first light emitting chip 120 is positioned between the first substrate 122 and the substrate 110. In some embodiments, the first light emitting layer 124 includes multiple light emitting elements, for example, light emitting diodes, laser diodes, quantum dots, or other elements with similar property, and the disclosure is not limited thereto. In some embodiments, the first light emitting layer 124 is formed on the first surface 122A of the first substrate 122 by means of epitaxy. Therefore, when the first light emitting layer 124 is subjected to external frictional force, it may easily peel off from the first surface 122A of the first substrate 122.

As shown in FIG. 1, the common metal layer 126 is positioned between the substrate 110 and the first light emitting chip 120. Therefore, the first light emitting chip 120 may be electrically connected with the first anode 160A and the cathode 160B via the common metal layer 126 and the substrate 110. Therefore, the emission state of the first light emitting layer 124 of the first light emitting device 120 may be controlled by means of the first anode 160A and the cathode 160B.

In some embodiments, the material of the common metal layer 126 includes indium (In), tin (Sn), copper (Cu), silver (Ag), bismuth (Bi) or their alloys, or other suitable materials, and the disclosure is not limited thereto.

The second light emitting chip 130 is disposed on the first light emitting chip 120, used to emit second color light L2 different from the first color light L1. The second light emitting chip 130 includes a second substrate 132 and a second light emitting layer 134.

In some embodiments, the first color light L1 is green light, and the second color light L2 is blue light. In other embodiments, the first color light L1 is blue light, and the second color light L2 is green light. In some embodiments, the wavelength range of the blue light is 430 nm to 480nm, and the wavelength range of the green light is 500nm to 560nm.

The second substrate 132 includes a third surface 132A, and a fourth surface 132B opposite to the third surface 132A. In some embodiments, the material of the second substrate 132 may be aluminum oxide, namely sapphire, or materials with similar property, and the disclosure is not limited thereto. In some embodiments, the second substrate 132 is transparent to the first color light L1, to prevent absorption of the first color light L1.

In some embodiments, the orthographic projection of the fourth surface 132B in vertical direction is positioned within the second surface 122B. That is, the second substrate 132 is completely positioned within the first substrate 122.

In some embodiments, the area of the second surface 122B is larger than the area of the fourth surface 132B. The area of the fourth surface 132B is 25% to 80% of the area of the second surface 122B. That is, the second substrate 132 is completely positioned within the first substrate 122.

The second light emitting layer 134 is positioned on the third surface 132A, used to emit the second color light L2. Specifically, the second light emitting layer 134 of the second light emitting chip 130 is positioned on the third surface 132A of the second substrate 132 away from the substrate 110. In some embodiments, the second light emitting layer 134 includes multiple light emitting elements, such as light emitting diodes, laser diodes, quantum dots, or other elements with similar property, and the disclosure is not limited thereto. In some embodiments, the second light emitting layer 134 is formed on the third surface 132A of the second substrate 132 by means of epitaxy. Therefore, when the second light emitting layer 134 is subjected to external frictional force, it may easily peel off from the third surface 132A of the second substrate 132.

As shown in FIG. 1, the second light emitting chip 130 further includes electrodes 136 positioned on the second light emitting layer 134. Therefore, the second light emitting layer 134 may be electrically connected to the second anode 160C via one of the electrodes 136 and one of the bonding pads 150 with one of wires 138 through the substrate 110, and electrically connected to the cathode 160B via the other one of the electrodes 136 and the other one of the bonding pads 150 with the other one of the wires 138 through the substrate 110. Therefore, the emission state of the second light emitting layer 134 of the second light emitting device 130 may be controlled by means of the second anode 160C and the cathode 160B.

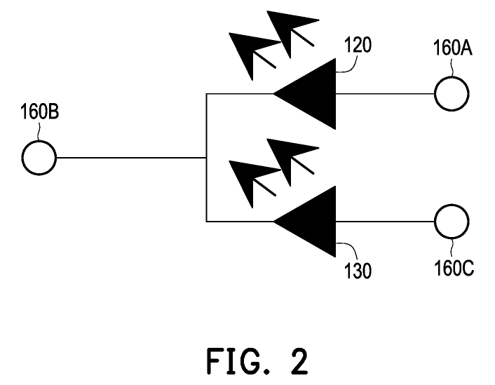

In this embodiment, the first light emitting chip 120 and the second light emitting chip 130 have the same cathode 160B. Please refer to FIG. 2. FIG. 2 is a circuit schematic diagram of a first light emitting chip and a second light emitting chip according to an embodiment of the disclosure. As mentioned in the previous explanation, the light emitting device 100 may control the emission state of the first light emitting layer 124 of the first light emitting device 120 by means of the first anode 160A and the cathode 160B, and control the emission state of the second light emitting layer 134 of the second light emitting device 130 by means of the second anode 160C and the cathode 160B. Since the first light emitting device 120 and the second light emitting device 130 share the cathode, the number of electrodes required for operating the first light emitting device 120 and the second light emitting device 130 can be reduced.

Please refer back to FIG. 1. As shown in FIG. 1, the second surface 122B of the first substrate 122 and the fourth surface 132B of the second substrate 132 are opposite to each other. Therefore, the first light emitting chip 120 and the second light emitting chip 130 are in a back-to-back configuration method, where the first light emitting layer 124 of the first light emitting chip 120 does not contact the second substrate 132 of the second light emitting chip 130, and the second light emitting layer 134 of the second light emitting chip 130 also does not contact the first substrate 122 of the first light emitting chip 120. By means of this back-to-back configuration method, it may prevent damage to the first light emitting layer 124 and the second light emitting layer 134 caused by direct contact with the second substrate 132 and the first substrate 122, such as peeling off from the first substrate 122 or the second substrate 132.

As shown in FIG. 1, the light emitting device 100 further includes a die attach layer 140, positioned between the first light emitting chip 120 and the second light emitting chip 130. In some embodiments, the die attach layer 140 is a transparent material, to prevent absorption of the first color light L1 emitted by the first light emitting device 120. In some embodiments, the die attach layer 140 is an electrically insulating material, to prevent the first light emitting device 120 and the second light emitting device 130 from forming an electrical connection by means of the die attach layer 140. In some embodiments, the material of the die attach layer 140 may be silicone-base adhesive material or epoxy resin adhesive material, or those having similar function, the disclosure is not limited thereto.

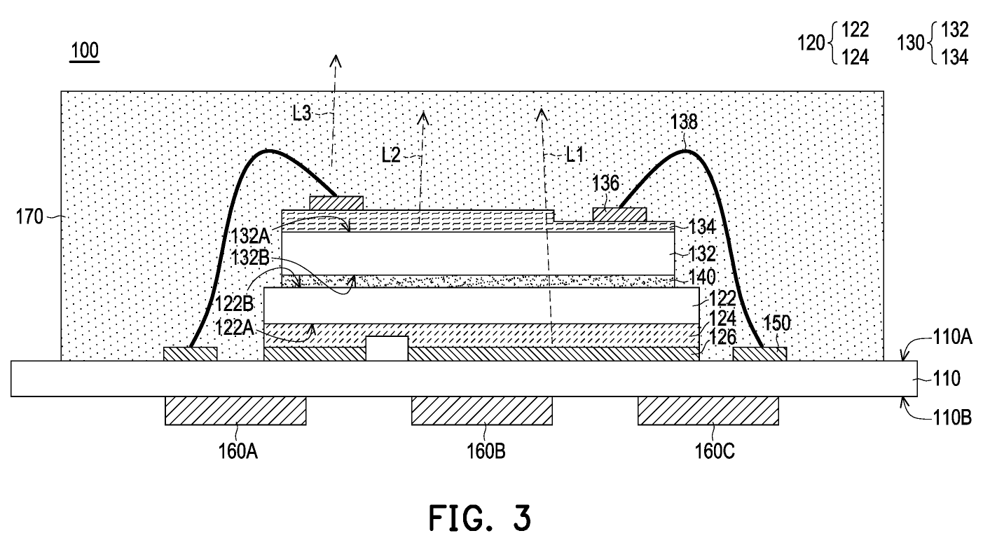

FIG. 3 is a schematic diagram of a light emitting device according to an embodiment of the disclosure. Please refer to FIG. 3. The light emitting device 100 shown in FIG. 3 is similar to the light emitting device 100 shown in FIG. 1, with the difference being that in FIG. 3, it further includes an encapsulant 170, to cover the substrate 110, the first light emitting chip 120, and the second light emitting chip 130 and to protect the wires 138. In some embodiments, the encapsulant 170 is a transparent material including molding compound, polymer material, such as silicone-base adhesive material or epoxy resin adhesive material, combinations thereof or other suitable materials.

In some embodiments, if the light emitting device 100 needs to emit white light, then the encapsulant 170 further includes phosphor. After being illuminated by the first color light L1 and the second color light L2, the phosphor emits third color light L3 that is different from the first color light L1 and the second color light L2. In some embodiments, the third color light L3 is red light, with a wavelength range of 590nm to 660nm. In some embodiments, the phosphor is a red phosphor A₂BF₆: Mn⁴⁺, where A may be K, Na, Ba, and B may be Si, Ti, Zr, Al, such as K₂SiF₆:Mn⁴⁺(KSF).

Therefore, by means of the light emitting device 100 as shown in FIG. 3, the light emitting device may simultaneously emit the first color light and the second color light which are green light and blue light, as well as the third color light which is red light, thereby emitting white light.

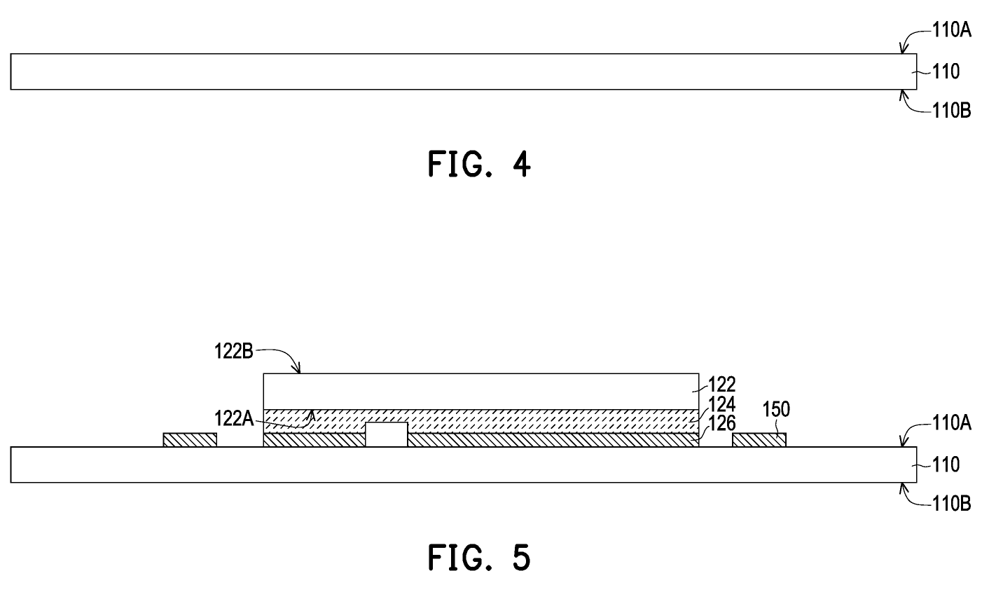

FIG. 4 to FIG. 9 are process flow diagrams for manufacturing a light emitting device according to an embodiment of the disclosure.

Please refer to FIG. 4. The substrate 110 is provided. The substrate 110 has the surface 110A and the surface 110B opposite to each other.

Please refer to FIG. 5. The first light emitting chip 120 is electrically connected to the substrate 110 by flip chip method. The first light emitting chip 120 includes the first substrate 122 and the first light emitting layer 124. The common metal layer 126 is positioned between the substrate 110 and the first light emitting chip 120. Therefore, the first light emitting chip 120 may be electrically connected to the substrate 110 via the common metal layer 126. Please refer to FIG. 5, the bonding pad 150 is formed on the surface 110A of the substrate 110, and the bonding pad 150 is electrically connected to the substrate 110.

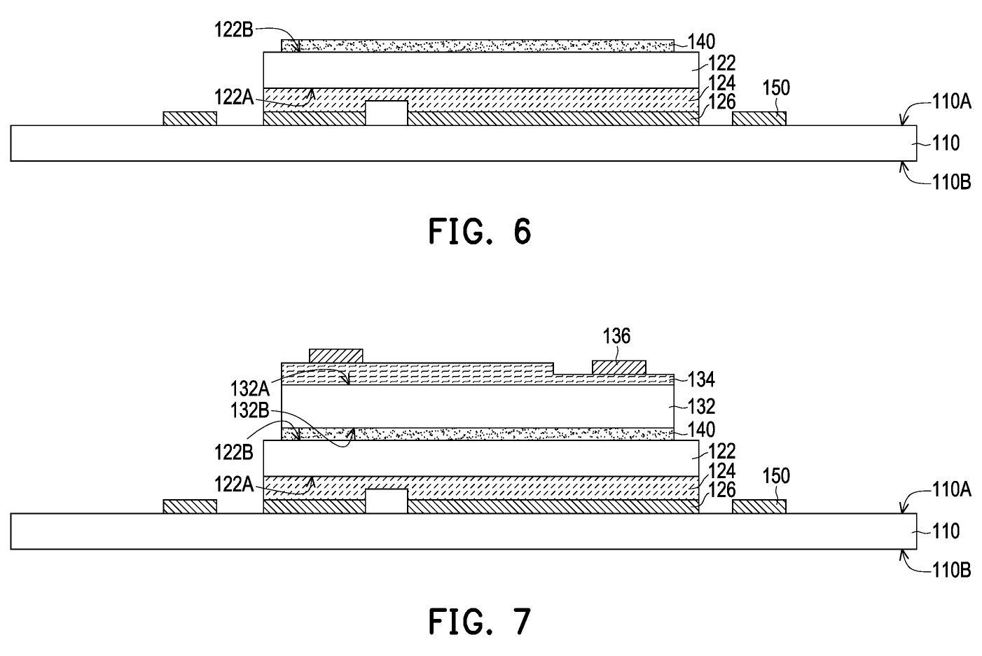

Please refer to FIG. 6. The die attach layer 140 is formed on the second surface 122B of the first substrate 122 of the first light emitting chip 120. In some embodiments, the die attach layer 140 is an electrically insulating material, the material of the die attach layer 140 may be silicone-base adhesive material or epoxy resin adhesive material, or one that has similar function, and the disclosure is not limited thereto.

Please refer to FIG. 7. The second light emitting chip 130 is disposed on the die attach layer 140 by mount method. The second light emitting chip 130 includes the second substrate 132 and the second light emitting layer 134. The fourth surface 132B of the second substrate 132 of the second light emitting chip 130 is connected with the die attach layer 140. And electrodes 136 are formed on the second light emitting layer 134 of the second light emitting chip 130.

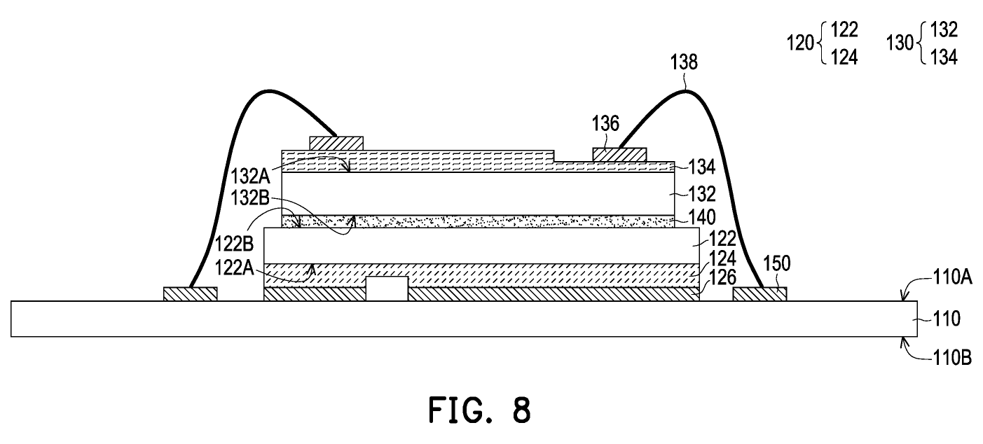

Please refer to FIG. 8. The wire 138 is electrically connected between the electrode 136 and the bonding pad 150 by wire bonding method.

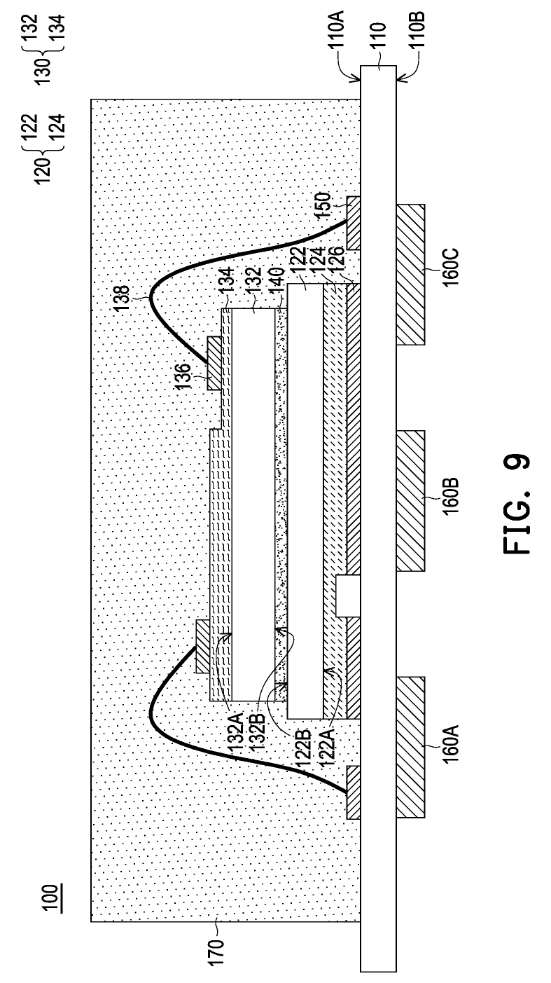

Please refer to FIG. 9. The encapsulant 170 is formed on the substrate 110 to cover the substrate 110, the first light emitting chip 120, and the second light emitting chip 130, and to protect the wires 138. In some embodiments, the encapsulant 170 is a transparent material including molding compound, polymer material, such as silicone-base adhesive material or epoxy resin adhesive material, combinations thereof, or other suitable materials.

The first anode 160A, the cathode 160B, and the second anode 160C are formed on the surface 110B of the substrate 110 and are electrically connected to the substrate 110. The first light emitting chip 120 may be electrically connected to the first anode 160A and the cathode 160B respectively through the common metal layer 126 and the substrate 110. Therefore, the emission state of the first light emitting layer 124 of the first light emitting device 120 may be controlled by means of the first anode 160A and the cathode 160B. In addition, the second light emitting layer 134 may be electrically connected to the second anode 160C via one of the electrodes 136 and one of the bonding pads 150 with one of the wires 138 through the substrate 110, and electrically connected to the cathode 160B via the other one of the electrodes 136 and the other one of the bonding pads 150 with the other one of the wires 138 through the substrate 110. Therefore, the emission state of the second light emitting layer 134 of the second light emitting device 130 may be controlled by means of the second anode 160C and the cathode 160B.

In summary, by means of connecting the first light emitting chip with the substrate by flip chip method, and connecting the second light emitting chip located on the first light emitting chip with the substrate by mount method, the color mura phenomenon between different color lights may be effectively improved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A light emitting device, comprising:
a substrate;
a first light emitting chip, the first light emitting chip being disposed on the substrate to emit first color light, the first light emitting chip comprising a first substrate and a first light emitting layer, the first substrate comprising a first surface and a second surface opposite to the first surface, the first light emitting layer being positioned on the first surface;
a second light emitting chip, the second light emitting chip being disposed on the first light emitting chip to emit second color light different from the first color light, the second light emitting chip comprising a second substrate and a second light emitting layer, the second substrate comprising a third surface and a fourth surface opposite to the third surface, the second light emitting layer being positioned on the third surface;
wherein the second surface and the fourth surface are opposite to each other.

2. The light emitting device according to claim 1, wherein an orthographic projection of the fourth surface in a vertical direction is located within the second surface.

3. The light emitting device according to claim 1, wherein an area of the second surface is greater than an area of the fourth surface.

4. The light emitting device according to claim 1, wherein an area of the fourth surface is 25% to 80% of an area of the second surface.

5. The light emitting device according to claim 1, wherein the first color light is green light, and the second color light is blue light.

6. The light emitting device according to claim 1, wherein the first color light is blue light, and the second color light is green light.

7. The light emitting device according to claim 1, wherein the first light emitting chip and the second light emitting chip have the same cathode.

8. The light emitting device according to claim 1, further comprising:
a common metal layer, positioned between the substrate and the first light emitting chip; and
a first anode, positioned on the substrate; and
a cathode, positioned on the substrate,
wherein the first light emitting chip is electrically connected to the first anode and the cathode respectively via the common metal layer.

9. The light emitting device according to claim 8, further comprising:
a plurality of bonding pads, wherein the bonding pads are positioned on the substrate; and
a second anode, positioned on the substrate,
wherein the second light emitting layer is electrically connected to the second anode via a first bonding pad of the bonding pads with a first wire of a plurality of wires,
wherein the second light emitting layer is electrically connected to the cathode via a second bonding pad of the bonding pads with a second wire of the wires.

10. The light emitting device according to claim 1, further comprising:
a die attach layer, positioned between the first light emitting chip and the second light emitting chip,
wherein the die attach layer is transparent and electrically insulating.

11. The light emitting device according to claim 1, wherein the first light emitting chip is electrically connected to the substrate by a flip chip method, and the second light emitting chip is electrically connected to the substrate by a mount method.

12. The light emitting device according to claim 1, wherein the first substrate is transparent to the first color light, and the second substrate is transparent to the first color light.

13. The light emitting device according to claim 1, wherein a wavelength range of the first color light is 430nm to 480nm, and a wavelength range of the second color light is 500nm to 560nm.

14. The light emitting device according to claim 1, wherein a wavelength range of the first color light is 500nm to 560nm, and a wavelength range of the second color light is 430nm to 480nm.

15. The light emitting device according to claim 1, further comprising an encapsulant to cover the substrate, the first light emitting chip, and the second light emitting chip, wherein the encapsulant comprises phosphor, after being illuminated by the first color light and the second color light, the phosphor emits third color light different from the first color light and the second color light.

16. The light emitting device according to claim 15, wherein the third color light is red light.

17. A light emitting device, comprising:
a substrate;
a first light emitting chip, having a first substrate and a first light emitting layer disposed on the first substrate; and
a second light emitting chip, having a second substrate and a second light emitting layer disposed on the second substrate,
wherein the first substrate and the second substrate are connected through a die attach layer.
